(19) United States
(12) Patent Application Publication
(10) Pub. No.: US 2012/0138595 A1
(43) Pub. Date: Jun. 7, 2012

(54) FLEXIBLE HEATER AND METHOD FOR MANUFACTURING SAME

(75) Inventors: Hideharu Watakabe, Yamaguchi (JP); Fumio Aoki, Chiba (JP); Shuichi Hashiguchi, Chiba (JP); Hideki Ozawa, Chiba (JP)

(73) Assignee: Ube Industries, Ltd., Yamaguchi (JP)

(21) Appl. No.: 13/306,462

(22) Filed: Nov. 29, 2011

(30) Foreign Application Priority Data
Dec. 2, 2010 (JP) 2010-269660

(51) Int. Cl. H05B 3/36; H05K 13/00

(52) U.S. Cl. 219/528; 29/846

(57) ABSTRACT

Provided are flexible heater excellent in heat resistance and in terminal strength, and a method for manufacturing same. A flexible heater 2 includes: a based member 10; a heating element circuit 12 formed on the base member 10; a heating element circuit cover member 14 which covers the heating element circuit 12; and a pair of lead wires 17 and 17 connected to a pair of connection end portions 12a and 12a of heating element circuit 12. The heating element circuit cover member 14 has opened portions 14a and 14a for not covering connection end portions 12a and 12a and their surroundings. The connection end portions 12a and 12a and their surroundings, and portions of the lead wires 17 and 17 above the base member 10 are covered through a heat-resistant adhesive 20 with an end portion cover member 22 provided separately from heating element circuit cover member 14.

### CROSS REFERENCE TO RELATED APPLICATIONS

This application is based on and claims the benefit of priority from prior Japanese Patent Application No. 2010-269660, filed on Dec. 2, 2010, the entire contents of which are incorporated herein by reference.

### BACKGROUND OF THE INVENTION

1. Field of the Invention

The present invention relates to a polyimide flexible heater obtained by covering a heating element circuit with a polyimide film, and a method for manufacturing the same.

2. Description of the Related Art

Flexible heaters obtained by covering a heating element circuit with stacked layers of highly heat-resistant polyimide cover films have already been proposed in Patent Documents 1 and 2, etc.

Patent Document 1 proposes a flexible heater covered by thermal fusing with a multilayer polyimide film including a thermally-fusible layer. However, the terminal region of this flexible heater to which a lead wire is joined is not covered. In Patent Document 2, the terminal region to which a lead wire is joined is covered, wherein in order to flatten the terminal region, a thermoplastic polyimide resin is placed near the terminal region, after which the whole components are simultaneously subjected to thermo-compression bonding. In this case, there is a risk that the resin used for flattening the terminal region might flow into the heater circuit region to damage the heat resistance of the heater. Furthermore, because covering the whole heater including the lead wire joined thereto is by heating it to 300 to 450° C., there is a limitation on the resin-coated wire that can be used as the lead wire in terms of heat resistance.
[Patent Document 1] Unexamined Japanese Patent Application Publication No. 2004-355882
[Patent Document 2] Unexamined Japanese Patent Application Publication No. 2008-123869

### SUMMARY OF THE INVENTION

An object of the present invention is to provide a flexible heater excellent in the heat resistance and also excellent in the terminal strength, and a method for manufacturing the same.

A flexible heater according to the present invention includes: a base member made of a multilayer polyimide film having a thermally-fusible polyimide surface layer on at least one surface thereof; a heating element circuit formed on the thermally-fusible polyimide surface layer of the base member; a heating element circuit cover member which is made of a multilayer polyimide film having thermally-fusible polyimide surface layers on both surfaces thereof and covers the heating element circuit; and a pair of lead wires connected to a pair of connection end portions of the heating element circuit, wherein the heating element circuit cover member has opened portions so as not to cover the connection end portions and their surroundings, and the connection end portions and their surroundings, and portions of the lead wires that are located above the base member are covered through a heat-resistant adhesive with an end portion cover member which is provided separately from the heating element circuit cover member and made of a multilayer polyimide film having a thermally-fusible polyimide surface layer on at least one surface thereof.

In the flexible heater according to the present invention, the end portion cover member may have a concave-shaped portion conforming to a surface shape of the lead wires connected to the connection end portions.

In the flexible heater according to the present invention, the thermally-fusible polyimide surface layer of the multilayer polyimide films used as the base member, the heating element circuit cover member, and the end portion cover member may have a glass transition point of 200 to 300° C., and a polyimide layer of the multilayer polyimide films except the thermally-fusible polyimide surface layer may have a glass transition point of 300° C. or higher.

In the flexible heater according to the present invention, the heat-resistant adhesive may be a heat-resistant adhesive which contains polyimide siloxane and a compound containing an epoxy group.

A method for manufacturing a flexible heater according to the present invention includes: a step of forming a heating element circuit on a thermally-fusible polyimide surface layer of a base member which is made of a multilayer polyimide film having a thermally-fusible polyimide surface layer on at least one surface thereof; a step of covering the heating element circuit with a heating element circuit cover member which is made of a multilayer polyimide film having thermally-fusible polyimide surface layers on both surfaces thereof and has opened portions so as not to cover connection end portions of the heating element circuit and their surroundings; a step of connecting lead wires to the connection end portions of the heating element circuit; and a step of covering, through a heat-resistant adhesive, the connection end portions and their surroundings, and portions of the lead wires that are located above the base member with an end portion cover member which is made of a multilayer polyimide film having a thermally-fusible polyimide surface layer on at least one surface thereof and provided separately from the heating element circuit cover member.

As described above, according to the present invention, it is possible to provide a flexible heater excellent in the heat resistance and also excellent in the terminal strength, and a method for manufacturing the same. Since there is no need of heating the terminal regions to which lead wires are joined to a high temperature, it is possible to use a resin-coated wire having a relatively low heat resistance.

### BRIEF DESCRIPTION OF THE DRAWINGS

FIG. 1 is a plan view of an embodiment of a flexible heater according to the present invention.

FIG. 2 is a cross-sectional diagram taken along a line A-A′ of FIG. 1.

FIG. 3 is a partial cross-sectional diagram taken along a line B-B′ of FIG. 1.

FIGS. 4A to 4D are diagrams showing the steps of manufacturing the flexible heater according to the present embodiment.

FIG. 5 is a plan view showing an example of a circuit substrate.

FIG. 6 is a front cross-sectional diagram showing an example of a method of covering the circuit substrate.

FIG. 7 is a plan view showing an example of joining between a lead wire and a terminal block.

FIG. 8 is a front cross-sectional diagram showing an example of a method of covering end portions and their surroundings.

### DETAILED DESCRIPTION OF THE EMBODIMENTS

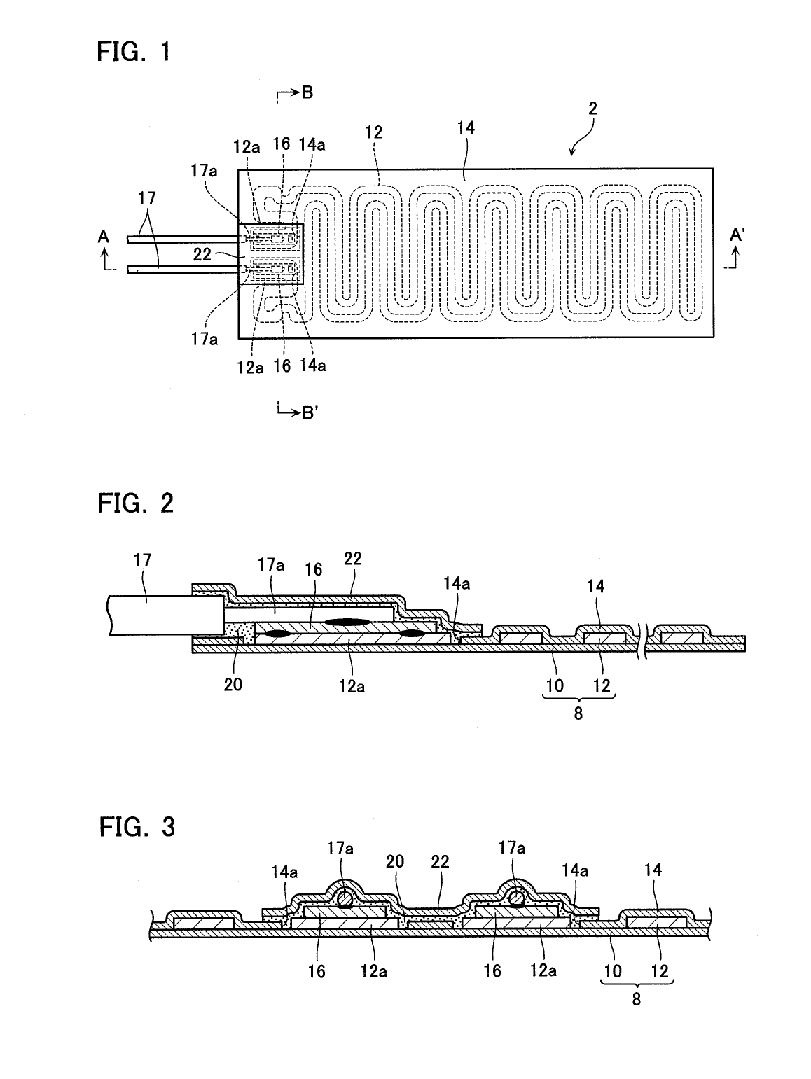

An embodiment of the flexible heater according to the present invention will now be explained with reference to FIG. 1 to FIG. 3. The flexible heater 2 according to the present embodiment comprises a base member 10, a heating element circuit 12 formed on the top surface of the base member 10, a heating element circuit cover member 14 which covers the heating element circuit 12, and a pair of lead wires 17 and 17 connected through terminals 16 and 16 to a pair of connection end portions 12a and 12a of the heating element circuit 12. The heating element circuit cover member 14 has holes 14a and 14a so as not to cover the connection end portions 12a and 12a and their surroundings, the terminals 16 and 16, and the lead wires 17 and 17. The connection end portions 12a and 12a and their surroundings, the terminals 16 and 16, and the lead wires 17 and 17 are covered through a heat-resistant adhesive 20 with an end portion cover member 22 which is formed as a different member from the heating element circuit cover member 14.

In the present embodiment, the base member 10 and the end portion cover member 22 are made of a multilayer polyimide film including a thermally-fusible polyimide surface layer on at least one surface thereof. The heating element circuit cover member 14 is made of a multilayer polyimide film including thermally-fusible polyimide surface layers on both surfaces thereof. In the present embodiment, a multilayer polyimide film including a thermally-fusible polyimide surface layer is a multilayer polyimide film which includes a thermally-fusible polyimide surface layer on its surface, and examples include a multilayer polyimide film having a two-layered or three-layered structure made of [a thermally-fusible polyimide surface layer/a polyimide layer(/a thermally-fusible polyimide surface layer)]. Such a multilayer polyimide film can be obtained by, for example, laminating a polyimide precursor solution, from which a thermally-fusible polyimide surface layer is produced, onto at least one surface or both surfaces of a polyimide layer by co-extrusion.

In the present embodiment, it is preferable that the thermally-fusible polyimide surface layer of the multilayer polyimide film having thermal fusibility be made from thermally-fusible polyimide that becomes bonded by thermo-compression bonding in the temperature range of 300 to 400° C. Preferably, the glass transition point of the thermally-fusible polyimide is 200 to 300° C.

Thermally-fusible polyimide is preferably made from 1,3-bis (4-aminophenoxy)benzene (hereinafter may be abbreviated as TPE-R) and 2,3,3′,4′-biphenyltetracarboxylic dianhydride (hereinafter may be abbreviated as a-BPDA). Alternatively, thermally-fusible polyimide is made from 1,3-bis (4-aminophenoxy)-2,2-dimethylpropane (DANPG) and 4,4′-oxydiphthalic acid dianhydride (ODPA). Yet alternatively, thermally-fusible polyimide is made from 4,4′-oxydiphthalic acid dianhydride (ODPA) and pyromellitic acid dianhydride, and 1,3-bis(4-aminophenoxy)benzene. Still alternatively, thermally-fusible polyimide is made from 1,3-bis(3-aminophenoxy)benzene and 3,3′,4,4′-benzophenonetetracarboxylic dianhydride, or from 3,3′-diaminobenzophenone and 1,3-bis(3-aminophenoxy)benzene, and 3,3′,4,4′-benzophenonetetracarboxylic dianhydride. Yet further, such thermally-fusible polyimide is also preferable which contains tetracarboxylic acid components wherein of 100 mol %, pyromellitic acid dianhydride accounts for 12 to 25 mol %, 3,3′4,4′-benzophenonetetracarboxylic acid dianhydride accounts for 5 to 15 mol %, and 3,3′4,4′-biphenyltetracarboxylic acid dianhydride accounts for the rest, and contains 1,3-bis(4-aminophenoxy)benzene as an indispensable diamine component, and of which Tg can be measured by DSC.

Any other tetracarboxylic acid dianhydride such as 3,3,4,4′-biphenyltetracarboxylic dianhydride, 2,2-bis(3,4-dicarboxyphenyl)propane dianhydride, etc. may be substituted in this thermally-fusible polyimide at a level at which the thermal fusibility is not spoiled.

In a method for producing the thermally-fusible polyimide, the respective components described above, and as the case may be, any other tetracarboxylic acid dianhydride and any other diamine may be reacted in an organic solvent at a temperature of approximately 100° C. or lower, and particularly 20 to 60° C. to produce a polyamic acid solution. The obtained polyamic acid solution can be used as a dope solution.

It is preferable that the polyamic acid solution, which is the precursor solution of the thermally-fusible polyimide, have a ratio of mole number of acid components of preferably, 0.92 to 1.1, particularly 0.98 to 1.1, and more particularly 0.99 to 1.1 with respect to the mole number of diamines. Further, in order to restrict gelation of the polyamic acid, when polymerizing polyamic acid, it is possible to add a phosphorus stabilizer such as triphenyl phosphite, triphenyl phosphate, etc. in the range of 0.01 to 1% with respect to the solid content (polymer) concentration. Furthermore, in order to promote imidization, it is possible to add a basic organic compound catalyst in the solution. For example, imidazole, 2-imidazole, 1,2-dimethylimidazole, 2-phenylimidazole, etc. can be used at a ratio of 0.01 to 20 wt %, and particularly 0.5 to 10 wt % with respect to polyamic acid (solid content). They are used in order to avoid insufficient imidization, because formation of the polyimide film is carried out at a relatively low temperature. Yet further, in order to stabilize the bonding strength, an organic aluminum compound, an inorganic aluminum compound, or an organic tin compound may be added in a thermally-fusible aromatic polyimide material dope. For example, aluminum hydroxide, aluminum triacetylacetonate, etc. as an aluminum metal can be added to polyamic acid (solid content) at a ratio of 1 ppm or higher, and particularly 1 to 1000 ppm.

The organic solvent used for producing the polyamic acid solution described above may be N-methyl-2-pyrrolidone, N,N-dimethylformamide, N,N-dimethylacetamide, N,N-diethylacetamide, dimethylsulfoxide, hexamethylphosphoramide, N-methylcaprolactam, cresols, etc., which can be used for both of a highly heat-resistant aromatic polyimide and a thermally-fusible aromatic polyimide. These organic solvents may be used solely, or in combination of two or more.

In the present embodiment, it is preferable that polyimide from which the polyimide layer of the multilayer polyimide film except the thermally-fusible polyimide surface layer(s) is made be a highly heat-resistant polyimide which has a glass transition point of 300° C. or higher or exhibits no glass transition point. The highly heat-resistant polyimide is preferably made from 3,3′,4,4′-biphenyltetracarboxylic dianhydride (hereinafter may be abbreviated as s-BPDA) and paraphenylenediamine (hereinafter may be abbreviated as PPD), and as the case may be, 4,4′-diaminodiphenylether (hereinafter may be abbreviated as DADE) and/or pyromellitic acid dianhydride (hereinafter may be abbreviated as PMDA). In this case, it is preferable that PPD/DADE (mole ratio) be 100/0 to 85/15. It is also preferable that s-BPDA/PMDA be 100/0 to 50/50.

The highly heat-resistant polyimide is also made from pyromellitic acid dianhydride, and paraphenylenediamine and 4,4′-diaminodiphenylether. In this case, it is preferable that DADE/PPD (mole ratio) be 90/10 to 10/90.

The highly heat-resistant polyimide is also made from 3,3′,4,4′-benzophenone tetracarboxylic dianhydride (BTDA) and pyromellitic acid dianhydride (PMDA), and paraphenylenediamine (PPD) and 4,4′-diaminodiphenylether (DADE). In this case, it is preferable that of the acid dianhydrides, BTDA account for 20 to 90 mol % and PMDA account for 10 to 80 mol %, and of the diamines, PPD account for 30 to 90 mol % and DADE account for 10 to 70 mol %.

Any other aromatic tetracarboxylic dianhydride and any other aromatic diamine such as 4,4′-diaminophenylmethane, etc. may be used in this highly heat-resistant polyimide at a level at which the properties of the polyimide are not spoiled.

In the co-extrusion/casting film formation method described above, it is preferable that, for example, the precursor solution of the thermally-fusible polyimide be co-extruded onto one surface or both surfaces of the highly heat-resistant polyimide, which is then casted onto a surface of a support such as a stainless specular surface, a belt surface, or the like, and brought into a semi-cured state or a dry state before that at 100 to 300° C. The semi-cured state or the state before that means a self-supporting state brought by heating and/or chemical imidization. The co-extrusion described above can be performed according to the co-extrusion method described in, e.g., Unexamined Japanese Patent Application Publication No. H3-180343 (Examined Japanese Patent Application Publication No. H7-102661) by feeding the material into a two-layered or three-layered extrusion die and casting the material onto a support.

It is possible to preferably obtain a multilayer polyimide film which includes a thermally-fusible polyimide surface layer on one surface or both surfaces of highly heat-resistant polyimide, by forming a multilayer film-like body by laminating the polyamic acid solution, from which thermally-fusible polyimide is produced, onto one surface or both surfaces of the highly heat-resistant polyimide, drying the multilayer film-like body, and after this, heating the multilayer film-like body at a temperature equal to or higher than the glass transition point (Tg) of the thermally-fusible polyimide and equal to or lower than the temperature at which deterioration occurs, preferably at the maximum heating temperature of equal to or higher than 375° C. and equal to or lower than 550° C. to dry and imidize the multilayer film-like body.

In the present embodiment, the thickness of the polyimide layer (base layer) of the multilayer polyimide film including a thermally-fusible polyimide surface layer is approximately 5 to 100 μm, and particularly approximately 7 to 50 μm. The thickness of the thermally-fusible polyimide surface layer is 1 to 10 μm, and particularly preferably 2 to 5 μm. If the surface layer thickness is smaller than 1 μm, it becomes harder to obtain a good bond performance by thermal fusion bonding. On the other hand, when the thickness is larger than 10 μm, the surface layer can be used, but produces no particular effect or rather deteriorates the heat resistance of the obtained polyimide heater.

It is preferable that the multilayer polyimide film including a thermally-fusible polyimide surface layer have a thickness of 10 to 100 μm, particularly 10 to 50 μm, and more particularly 10 to 25 μm. If the thickness is smaller than 10 μm, the obtained film is difficult to handle. If the thickness is larger than 100 μm, the film produces no particular effect or rather makes it difficult for itself to be thermo-compression bonded to the heating element for the thermally-fusible polyimide layer on one surface to fill the spaces other than the metal constituting the heating element, which is disadvantageous.

In the present embodiment, the heating element circuit 12 is formed on the top surface of the base member 10. A heating element made of a metal having a linear shape or a foil shape is used as the heating element circuit 12. Examples of the material include stainless, nickel alloy, Kanthal, inconel, cast iron, etc. having an electric resistance. Materials having a specific electric resistivity of 30×10⁻⁶ Ωcm or higher are preferable. Particularly, a heating element circuit made of a stainless foil or a nickel alloy foil is preferable. The heating element circuit 12 includes at least one pair of connection end portions 12a and 12a for positive and negative electrodes. The lead wires 17 and 17 are joined to the connection end portions 12a and 12a through the terminals 16 and 16.

A heating element circuit having a width of approximately 10 μm to 20 mm is preferable as the heating element circuit 12 made of a foil. A heating element circuit having a thickness of approximately 5 to 100 μm, and particularly approximately 5 to 50 μm is preferable.

The heating element circuit 12 according to the present embodiment can be obtained by a method of placing a mask on a metal foil such as stainless or the like and etching the metal foil by a ferric chloride solution according to a publicly-known etching method to form a substrate having a metal circuit made of stainless or the like. A sheet-like heating element circuit having a gap of approximately 50 μm to 20 mm between metal foils is preferable as such a heating element circuit 12.

In the present embodiment, the top surface of the heating element circuit 12 is covered with the heating element circuit cover member 14. The heating element circuit cover member 14 has at least some portions thereof rectangular holes 14a and 14a which are bored therethrough from the top surface to the bottom surface so as not to cover the connection end portions 12a and 12 of the heating element circuit and their surroundings, the terminals 16 and 16, and the lead wires 17 and 17. The portions and their surroundings that are not covered with the heating element circuit cover member 14 because of the holes 14a and 14a of the heating element circuit cover member 14, i.e., the connection end portions 12a and 12a of the heating element circuit and their surroundings, the terminals 16 and 16, and those portions of the lead wires 17 and 17 that are located above the base member 10 are covered through the heat-resistant adhesive 20 with the end portion cover member 22 having a rectangular shape. In the present embodiment, the holes 14a and 14a are formed as opened portions of the heating element circuit cover member 14, but the end portions may be formed to be opened in a planar direction.

In the present embodiment, with the end portion cover member 22 provided separately from the heating element circuit cover member 14, the connection end portions 12a and 12a of the heating element circuit and their surroundings, the terminals 16 and 16, and the lead wires 17 and 17 are covered with the end portion cover member 22 through the heat-resistant adhesive 20. By not covering the connection end portions 12a and 12a and their surroundings, the terminals 16 and 16, and the lead wires 17 and 17 with the heating element circuit cover member 14 but processing them differently from the other portions of the heating element circuit 12, it is possible to solve the problem that the heat-resistant adhesive 20 might flow into the heating element circuit 12 to damage the heat resistance of the heater.

In the present embodiment, the heat-resistant adhesive 20 used for bonding the connection end portions 12a and 12a and their surroundings, the terminals 16 and 16, and the lead wires 17 and 17 to the end portion cover member 22 may be anything as long as it has the required properties regarding heat resistance and bonding strength. Particularly, such an adhesive is preferable that can paste a metal of various kinds with a heat-resistant support member such as a heat-resistant film, sheet, etc. easily at a relatively low temperature, and keeps a high bonding strength at a high temperature after bonding and curing. The heating/curing temperature during bonding is preferably 140 to 300° C., and particularly preferably 150 to 280° C. It is also preferable that the adhesive be previously formed into a sheet-like component so that it can be used as inserted between the targets to be bonded.

By not covering the connection end portions 12a and 12a and their surroundings, the terminals 16 and 16, and the lead wires 17 and 17 and their surroundings with the heating element circuit cover member 14 like the other portions of the heating element circuit 12 are covered, but bonding the connection end portions 12a and 12a and their surroundings, the terminals 16 and 16, and the lead wires 17 and 17 to the end portion cover member 22 with the heat-resistant adhesive 20, it is possible to carry out the bonding process to them at a lower temperature than when they are to be covered with the heating element circuit cover member 14. Therefore, resin-coated wires having a low heat resistance can be used as the lead wires 17 and 17.

The heat-resistant adhesive 20 is preferably a heat-resistant adhesive that contains polyimide siloxane and a compound containing an epoxy group, and specifically, an adhesive that contains polyimide siloxane (a), epoxy polyoxyalkylene-modified polysiloxane (b), another epoxy compound containing an epoxy group (c), and an epoxy curing agent (d).

The polyimide siloxane (a) can be obtained by a method of polymerizing an aromatic tetracarboxylic component and diamine components including diaminopolysiloxane and aromatic diamine in an organic polar solvent at 15 to 250° C. by using the aromatic tetracarboxylic component and the diamine components at substantially equal mole ratio and adjusting the ratio of use between the diaminopolysiloxane and aromatic diamine appropriately. It is preferable that these components have as high a molecular weight as possible, be highly imidizable, and be dissolvable uniformly in the organic polar solution at least 3 wt % or higher, and particularly at a high concentration of approximately 5 to 40%, because an adhesive having a good bond performance can be obtained from such components.

The epoxy polyalkylene-modified polysiloxane (b) may be epoxy polyalkylene-modified polysiloxane that contains at least one epoxy group and one polyalkylene group at the end or within the polysiloxane. A preferable one has a melting point of 90° C. or lower, and is in a liquid state at 30° C. or lower. Generally, the epoxy polyalkylene-modified polysiloxane (b) is obtained by reacting a reactive polysiloxane oil having a terminal hydroxyl, carboxyl, or amino group with an epoxy compound such as a bisphenol epoxy resin, phenol-novolac epoxy resin, glycidyl ether epoxy resin, glycidyl ester epoxy resin, or the like, and polyalkylene such as polyoxypropylene, polyoxyethylene, or the like at the temperature of approximately 80 to 140° C.

Another epoxy compound containing an epoxy group (c) may be an epoxy compound containing one or more epoxy group(s), such as bisphenol A type or bisphenol F type epoxy resin, phenol-novolac epoxy resin, alkylpolyphenol epoxy resin, multifunctional epoxy resin, glycidyl ether epoxy resin, glycidyl ester epoxy resin, glycidyl amine epoxy resin, which may be used singly or in combination. Because an epoxy compound having an excessively high melting point will produce an adhesive which has a high softening point in an uncured state, an epoxy compound that has a melting point of 90° C. or lower and preferably 0 to 80° C., and is in a liquid state at 30° C. or lower is preferable.

The epoxy curing agent (d) may be a publicly-known curing agent such as a curing catalyst such as imidazole, tertiary amine, triphenyl phosphine, etc., a polyaddition curing agent such as dicyandiamide, hydrazine, aromatic diamine, a phenol-novolac curing agent containing a hydroxyl group, etc., and organic peroxide, etc., which can be used together with a publicly-known curing accelerator.

When these components are mixed in an organic solvent, a solution composition of the adhesive is produced. This solution composition is coated on the surface of a metal foil, a heat-resistant film such as an aromatic polyimide film, etc., or a thermoplastic film such as polyester, polyethylene, etc., and in order to eliminate the solvent to 1 wt % or lower, and particularly 0.5 wt % or lower, dried at a temperature that will not bring the adhesive to a cured state. Then, the adhesive is peeled and taken out from the foil or film. In this way, a thin film sheet of the adhesive in an uncured state (thickness: approximately 1 to 200 μm) can be obtained.

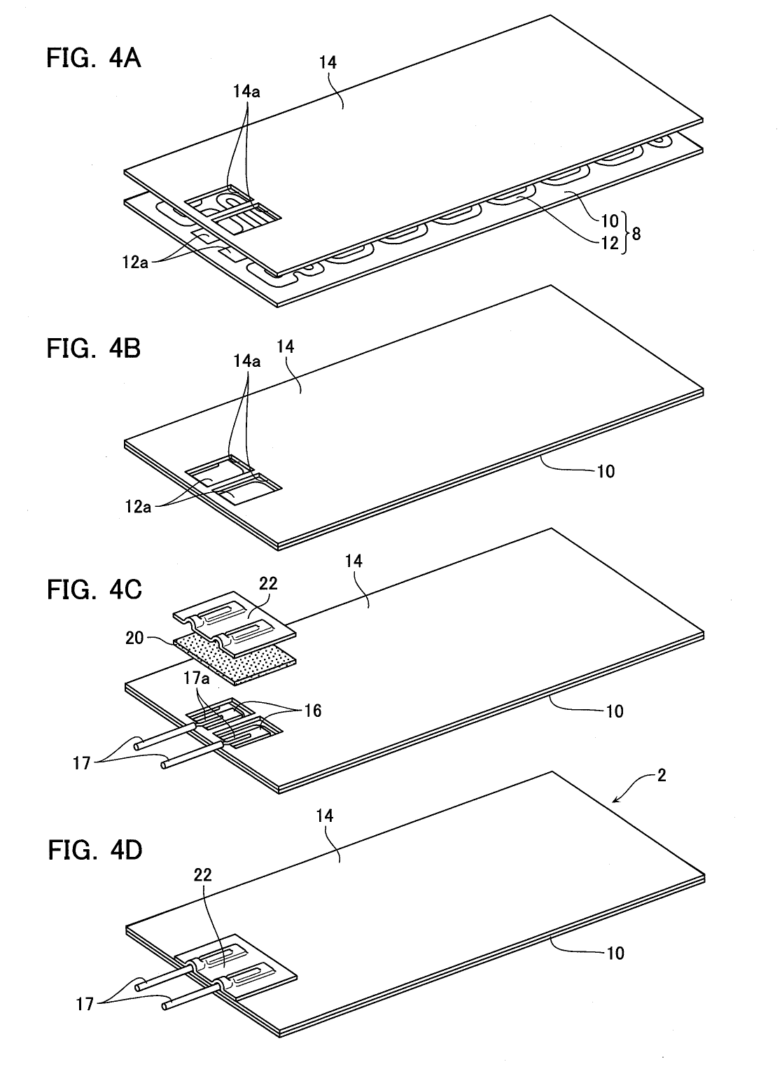

Next, a method for manufacturing the flexible heater 2 according to the present embodiment will be explained with reference to FIG. 4. The flexible heater 2 according to the present embodiment can be manufactured through the step (1) of forming the heating element circuit 12 on the thermally-fusible polyimide surface layer of the base member 10, the step (2) of covering the heating element circuit 12 with the heating element circuit cover member 14 having the holes 14a and 14a so as not to cover the connection end portions 12a and 12a of the heating element circuit 12 and their surroundings, the step (3) of connecting the terminals 16 and 16 and the lead wires 17 and 17 to the connection end portions 12a and 12a of the heating element circuit 12, and the step (4) of covering the connection end portions 12a and 12a and their surroundings, the terminals 16 and 16, and the lead wires 17 and 17 with the end portion cover member 22 formed separately from the heating element circuit cover member 14 through the heat-resistant adhesive 20.

In the step (1), first, a metal foil to become the heating element circuit 12 and a multilayer polyimide film to constitute the base member 10 are bonded by thermal fusion bonding, to form a stacked body made of the metal foil and the multilayer polyimide film.

A publicly-known method, for example, a hot press method can be employed for thermal fusion bonding of the metal foil and the multilayer polyimide film. The hot press temperature may be a temperature sufficient for the thermally-fusible polyimide surface layer of the multilayer polyimide to thermally fuse. When the glass transition point of the thermally-fusible polyimide surface layer is 200 to 300° C., the hot press temperature is preferably 250 to 450° C., and more preferably 300 to 400° C. The pressure is not particularly limited as long as it is such a level that would allow the adhesiveness to develop well. For example, the pressure may be 0.1 to 100 MPa, and preferably 0.1 to 50 MPa. It is preferable that the hot press be carried out under depressurization in order to prevent any residual air bubbles.

Then, by etching the metal foil by a publicly-known method, for example, an etching method using a ferric chloride solution, it is possible to form a predetermined heating element circuit 12 on the base member 10 easily.

The step (2) is a step of covering the heating element circuit 12 formed on the base member 10 with the heating element circuit cover member 14 having the holes 14a and 14a so as not to cover the connection end portions 12a and 12a of the heating element circuit 12 and their surroundings, as shown in FIGS. 4A and 4B. This step can be carried out by thermal fusion bonding under the same conditions as those of the hot press of the step (1). An improved adhesiveness can be obtained if the hot press temperature is set to equal to or higher than the glass transition point of the polyimide layer other than the thermally-fusible polyimide surface layer, which is preferable. For example, it is preferable that the hot press be carried out at the temperature of 300 to 400° C., at the pressure of 0.1 to 50 MPa, and under depressurization.

The step (3) is a step of connecting the lead wires 17 and 17 to the connection end portions 12a and 12a of the heating element circuit 12 through the terminals 16 and 16. Any conventionally publicly-known method may be employed as long as it can ensure sufficient connection, but this step can be carried out preferably by a welding method. Further, in order to maintain the flatness of the terminals 16 and 16, it is preferable that terminal blocks made of metal plates be welded to the leading ends 17a and 17a of the lead wires by a welding method, and the terminal blocks be joined to the connection end portions 12a and 12a of the heating element circuit by parallel welding.

The step (4) is a step of covering the connection end portions 12a and 12a and their surroundings, the terminals 16 and 16, and the lead wires 17 and 17 with the end portion cover member 22 formed separately from the heating element circuit cover member 14 through the heat-resistant adhesive 20, as shown in FIGS. 4D and 4C. In step (4), since the connection end portions 12a and 12a and their surroundings, the terminals 16 and 16, and the lead wires 17 and 17 are to be covered with a multilayer polyimide film, which is the end portion cover member 22, through the heat-resistant adhesive 20, they can be subjected to thermal fusion bonding at a lower temperature condition than in the step (1). The hot press condition may be such a temperature that brings the heat-resistant adhesive 20 to be bonded and cured, and preferably 140 to 300° C. The pressure is 0.1 to 50 MPa, and it is preferable that the hot press be carried out under depressurization. The amount and size of the heat-resistant adhesive film to be used as the heat-resistant adhesive 20 should be selected appropriately to fill the clearances around the terminals 16 and 16 to which the lead wires 17 and 17 are joined. The connection end portions 12a and 12a and their surroundings, the terminals 16 and 16, and the lead wires 17 and 17 are covered with the end portion cover member 22 at the same time as they are covered with the heat resistant adhesive 20. It is preferable that during thermal fusion bonding, a cushioning member having both heat resistance and flexibility such as silicone rubber sheet be used above the connection end portions 12a and 12a and their surroundings, the terminals 16 and 16, and the lead wires 17 and 17, such that any unevenness between them and the other portions are adjusted to allow the pressure to be applied uniformly. This is preferable because this will improve the deformation ratio of the lead wires of the flexible heater to be obtained.

When carrying out the step (4), it is preferable that the multilayer polyimide film to be the end portion cover member 22 to cover the connection end portions 12a and 12a and their surroundings, the terminals 16 and 16, and the lead wires 17 and 17 be previously molded into a concave shape conforming to the shape of the terminals 16 and 16, and the lead wires 17 and 17. In this case, it is preferable that hot press be carried out at the temperature of 150 to 350° C., at the pressure of 0.1 to 50 MPa, using a convex mold conforming to the shape of the terminals 16 and 16, and the lead wires 17 and 17.

Though embodiments of the present invention having been described, these embodiments are presented by way of example, and are not intended to limit the scope of the invention. These embodiments can be implemented in various other manners.

According to the present invention, the clearances around the connection end portions of the heating element circuit to which the lead wires are joined are filled with the heat-resistant adhesive. That is, the connection end portions to which the lead wires are joined are bonded to the multilayer polyimide film through the thermally-fusible polyimide surface layer of the multilayer polyimide film or through the heat-resistant adhesive placed above the connection end portions, and the clearances around the connection end portions are filled with the heat-resistant adhesive. Furthermore, the entire heating element circuit is previously covered with the multilayer polyimide film and integrated closely therewith. Therefore, the heat-resistant adhesive will not flow into the heating element circuit region, and even if the heater is used at a high temperature condition for a long time, the heater itself and also the terminal regions to which the lead wires are joined can be used stably for a very long time.

Furthermore, because covering the connection end portions and their surroundings is carried out separately from covering the heating element circuit, the hot press temperature can be suppressed to a low level. This reduces the level of the heat resistance which the lead wires are required to have when they are covered, allowing a wider range of selection for the lead wires.

The temperature at which the flexible heater according to the present invention is assured long-term safety, i.e., the temperature at which it takes 20,000 hours for the flexible heater to lose its tensile strength to half under a heat resistance test, is 250° C. or higher.

### EXAMPLES

Next, the present invention will be specifically explained using examples. However, the present invention is not limited to these examples.

Various measurements on the examples were carried out as follows.

(1) Measurement of Glass Transition Point

The glass transition point was obtained by measuring a differential heat by elevating the temperature by 20° C. per minute in nitrogen atmosphere by SSC5200 DSC320 provided by Seiko Instruments Inc.

(2) Measurement of 90 Degree Peel Strength

This measurement was carried out based on IPC-FC-241B.

(3) Measurement of Direct-Current Resistance

This measurement was carried out based on a test method 303 of MIL-STD-202G

(4) Measurement of Insulation Resistance

This measurement was carried out based on a test method 302 of MIL-STD-202G.

Applied voltage; 500 VDC

Application time; 1 minute

(5) Measurement of Withstand Voltage

This measurement was carried out based on a test method 301 of MIL-STD-202G

Applied voltage; 1000 VDC

Application time; 1 minute

(6) Terminal Strength Test

An end of the heater that is opposite to the terminal region was fixed to the upper chuck of a tensile tester, and the lead wires were fixed to the lower chuck. The heater was tensed at the speed of 2 mm/min, held for 10 seconds when the load reached 1.4 kg, and then released from the tensile tester.

(7) Humidity Resistance Test

The heater was put into a thermo-hygrostat chamber in which the temperature was kept to 40° C. and the relative humidity was kept to 90%, and stored therein for 90 hours.

(8) Heat Shock Test A

Heat shock cycles were applied a hundred times in the range from −65° C. to 175° C.

(9) Heat Shock Test B

The heater was put into a thermostatic chamber in which the temperature was kept to −65° C., and stored therein for 1 hour. After this, a voltage of 28 V was applied to the heater and the temperature was elevated. When the surface temperature of the heater reached 175° C., the application of the voltage was stopped. This operation was repeated a hundred times.

(10) Life Test

The heater was put into a thermostatic chamber in which the temperature was kept to −65° C., and stored therein for 1 hour. After this, a voltage of 28 V was applied to the heater and the temperature was elevated. When the surface temperature of the heater reached 120° C., the application of the voltage was stopped. This operation was repeated 20,000 times.

(11) High-Temperature Storage Test

High-Temperature Test 1

The heater was put into a thermostatic chamber in which the temperature was kept to 200° C., and stored therein for 30 hours.

High-Temperature Test 2

The heater was put into a thermostatic chamber in which the temperature was kept to 175° C., and stored therein for 1,000 hours.

### Example 1

(Manufacture of Sheet Member)

A polyimide film having a width and length of 100 mm and a thickness of 50 μm and having thermally-fusible layers on both surfaces thereof (Upilex-VT provided by Ube Industries, Ltd.; the glass transition temperature of the polyimide of the thermally-fusible layers is 240° C.) was used as the base member 10. This polyimide film was overlaid with a nickel-chromium alloy having a width and length of 100 mm and a thickness of 40 μm (provided by Sumitomo Metal Industries, Ltd.). Then, they were pressurized by a vacuum press in a vacuum at 330° C. for 5 minutes at 5 MPa, and thereby a sheet member formed of a polyimide film and a metal foil pasted together was formed. The 90 degree peel strength of this sheet member was 600 g/cm.

(Formation of Heating Element Circuit)

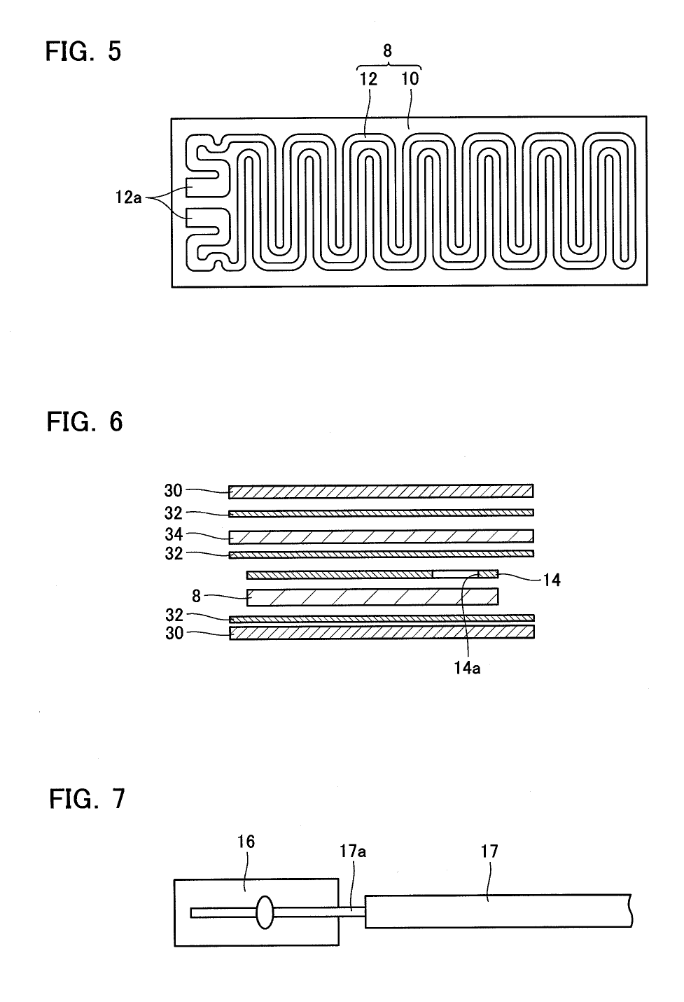

A photosensitive dry film was pasted on the metal foil side of the sheet member. They were exposed to ultraviolet through a photo mask, developed by alkaline developer, and etched by a ferric chloride solution, and the dry film was removed by an alkaline solution. Thereby, a circuit substrate 8 shown in FIG. 5 on which a heating element circuit 12 having a width of 76.2 mm and a length of 76.2 mm was formed was obtained.

(Covering of Circuit Substrate)

A polyimide film to serve as the heating element circuit cover member 14 having thermally-fusible layers on both surfaces thereof (Upilex-VT provided by Ube Industries, Ltd.; the glass transition temperature of the polyimide of the thermally-fusible layers is 240° C.) was cut into the same width and length as the sheet member, and punched at the portions corresponding to the connection end portions 12a and 12a of the heating element circuit and their surroundings by a width of 4 mm and a length of 6 mm. This film was overlaid on the circuit-formed side of the circuit substrate 8 such that the punched portions of the film coincide with the connection end portions 12a and 12a and their surroundings. Then, as shown in FIG. 6, a polyimide film 32, a fluorine resin plate 34, a polyimide film 32, and a stainless plate 30 were stacked on the upper side, and a polyimide film 32 and a stainless plate 30 were stacked on the lower side. They were pressurized by a vacuum press in a vacuum at 330° C. for 5 minutes at 5 MPa, to cause thermal fusion bonding of the heating element circuit cover member film 14 to the circuit substrate 8 and cover the circuit.

(Mounting of Lead Wires)

A portion 17a of a lead wire (M81381/17-26 provided by Junkosha Inc.) having a length of 300 mm, which portion 17a was stripped of coated resin, was joined by welding to a terminal block 16 which was made of a nickel-cobalt alloy (kovar provided by the Nilaco Corporation) having a width of 2.5 mm, a length of 5 mm, and a thickness of 0.1 mm and Au-plated on the entire surface to a thickness of 1.8 μm, as shown in FIG. 7. Next, the terminal blocks 16 and 16 to which the lead wires 17 and 17 were joined were joined by welding to the connection end portions 12a and 12a of the circuit substrate 8 like in FIG. 1.

(Manufacture of End Portion Cover)

A polyimide film having a thickness of 50 μm was cut into a width of 12 mm and a length of 18 mm, placed on a convex mold having a shape conforming to the shape of the terminal, fed to a press (a compression molding press YSR-10 provided by Shinto Metal Industries Corporation), and pressurized at 350° C. at a pressure of 5 MPa for 5 minutes. Thereby, an end portion cover polyimide film 22 conforming to the shapes of the terminal blocks 16 and 16 and the lead wires 17 and 17 was obtained.

(Covering of End Portions)

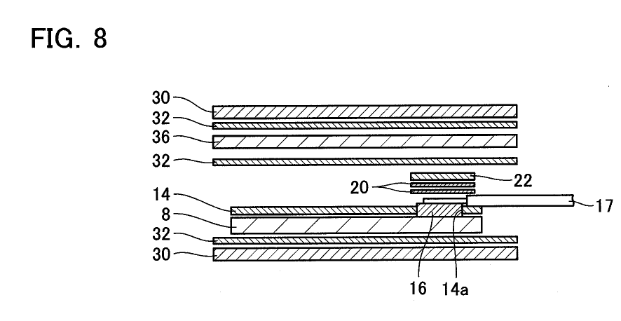

Two adhesive sheets 20 (Upitite UPA-N221C provided by Ube Industries, Ltd.) which were cut into a width of 12 mm and a length of 18 mm were placed on the connection end portions 12a and 12a and their surroundings of the circuit substrate 8 to which the lead wires were joined. Then, one sheet, which was the end portion cover polyimide film 22, was placed on the two adhesive sheets 20. A silicon rubber sheet 36 having a thickness of 1 mm was used as a cushioning member, and as shown in FIG. 8, a polyimide film 32, the silicon rubber sheet 36, a polyimide film 32, and a stainless plate 30 were stacked on the upper side, and a polyimide film 32 and a stainless plate 30 were stacked on the lower side. They were fed to a press (a compression molding press YSR-10 provided by Shinto Metal Industries Corporation), and pressurized at 250° C. at a pressure of 5 MPa for 5 minutes, to cover the end portions and complete the flexible heater. The direct-current resistance was within ±10% of the design diagram, the insulation resistance was 500 MΩ or higher, and no dielectric breakdown was observed.

After the terminal strength test was carried out on this heater, the direct-current resistance was measured, which turned out to be ±10% of the design diagram. After the high-temperature test 1 was carried out, the dielectric-current resistance of this heater was ±10% of the design diagram, and the insulation resistance was 1000 MΩ. No dielectric breakdown was observed after a withstand voltage.

After the humidity resistance test, the heat shock test A, the heat shock test B, and the high-temperature test 2 were carried out on this heater, the direct-current resistance was within ±10% of the design diagram, the insulation resistance was 500 MΩ or higher, and no dielectric breakdown was observed after a withstand voltage. The results are shown in Table 1.

### Examples 2 and 3

Examples 2 and 3 were implemented in the same manner as Example 1 except that covering of the connection end portions 12a and 12a and their surroundings was carried out at 240° C. and 260° C. respectively. The results are shown in Table 1.

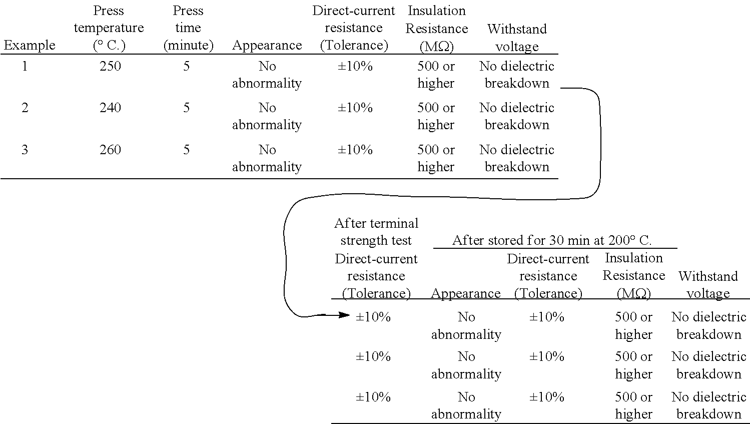

What is claimed is:

1. A flexible heater, comprising:
a base member made of a multilayer polyimide film having a thermally-fusible polyimide surface layer on at least one surface thereof;
a heating element circuit formed on the thermally-fusible polyimide surface layer of the base member;
a heating element circuit cover member which is made of a multilayer polyimide film having thermally-fusible polyimide surface layers on both surfaces thereof and covers the heating element circuit; and
a pair of lead wires connected to a pair of connection end portions of the heating element circuit,
wherein the heating element circuit cover member has opened portions so as not to cover the connection end portions and their surroundings, and
the connection end portions and their surroundings, and portions of the lead wires that are located above the base member are covered through a heat-resistant adhesive with an end portion cover member which is provided separately from the heating element circuit cover member and made of a multilayer polyimide film having a thermally-fusible polyimide surface layer on at least one surface thereof.

2. The flexible heater according to claim 1,
wherein the end portion cover member has a concave-shaped portion conforming to a surface shape of the lead wires connected to the connection end portions.

3. The flexible heater according to claim 1,
wherein the thermally-fusible polyimide surface layer of the multilayer polyimide films used as the base member, the heating element circuit cover member, and the end portion cover member has a glass transition point of 200 to 300° C., and a polyimide layer of the multilayer polyimide films except the thermally-fusible polyimide surface layer has a glass transition point of 300° C. or higher.

4. The flexible heater according to claim 2,
wherein the thermally-fusible polyimide surface layer of the multilayer polyimide films used as the base member, the heating element circuit cover member, and the end portion cover member has a glass transition point of 200 to 300° C., and a polyimide layer of the multilayer polyimide films except the thermally-fusible polyimide surface layer has a glass transition point of 300° C. or higher.

5. The flexible heater according to any of claims 1,
wherein the heat-resistant adhesive is a heat-resistant adhesive which contains at least polyimide siloxane and a compound containing an epoxy group.

6. The flexible heater according to any of claims 2,
wherein the heat-resistant adhesive is a heat-resistant adhesive which contains at least polyimide siloxane and a compound containing an epoxy group.

7. The flexible heater according to any of claims 3,
wherein the heat-resistant adhesive is a heat-resistant adhesive which contains at least polyimide siloxane and a compound containing an epoxy group.

8. The flexible heater according to any of claims 4,
wherein the heat-resistant adhesive is a heat-resistant adhesive which contains at least polyimide siloxane and a compound containing an epoxy group.

9. A method for manufacturing a flexible heater, comprising:
a step of forming a heating element circuit on a thermally-fusible polyimide surface layer of a base member which is made of a multilayer polyimide film having a thermally-fusible polyimide surface layer on at least one surface thereof;
a step of covering the heating element circuit with a heating element circuit cover member which is made of a multilayer polyimide film having thermally-fusible polyimide surface layers on both surfaces thereof and has opened portions so as not to cover connection end portions of the heating element circuit and their surroundings;
a step of connecting lead wires to the connection end portions of the heating element circuit; and
a step of covering, through a heat-resistant adhesive, the connection end portions and their surroundings, and portions of the lead wires that are located above the base member with an end portion cover member which is made of a multilayer polyimide film having a thermally-fusible polyimide surface layer on at least one surface thereof and provided separately from the heating element circuit cover member.
